(19) United States
(12) Patent Application Publication
(10) Pub. No.: US 2012/0160787 A1
(43) Pub. Date: Jun. 28, 2012

(54) PROFILE MEMBER FOR A SOLAR PANEL FRAME

(75) Inventor: Anja Schummlochner, Wolpertshausen (DE)

(73) Assignee: CONSTELLIUM EXTRUSIONS DUETSCHLAND GMBH, Crailsheim (DE)

(21) Appl. No.: 13/393,747

(22) PCT Filed: Aug. 30, 2010
(86) PCT No.: PCT/IB2010/002520

§ 371 Date: Mar. 1, 2012

(30) Foreign Application Priority Data
Sep. 4, 2009 (EP) 09/04203

(51) Int. Cl. H01L 23/32

(52) U.S. Cl. 211/41.1

(57) ABSTRACT

The invention relates to an extruded profile member for a solar panel frame, characterized in that said profile member comprises a cross-section defined by the surfaces for forming, after being shaped typically by being folded and clamped, a U-shaped cross-section for supporting the panel therein, and produced in a more open manner during the extrusion, such that said cross-section enables the panel to be positioned on one of the surfaces without the panel touching the other surfaces during said positioning process. The invention also relates to a solar panel frame made from such profile members.

### FIELD OF THE INVENTION

The invention relates to the field of solar panels, more precisely to the frames that surround the actual solar panels, more particularly still those frames that are built using extruded profile members, particularly made from aluminium alloy.

### PRIOR ART

The assemblies commonly called “solar panels” are in fact made up of two assemblies:

A central panel typically comprises two layers of material called “laminates”, which are generally PVC-based and contain solar cells, and one transparent protective layer, generally of a glazed material, typically glass, which covers the upper surface of the panel that faces the solar rays.

This assembly will hereafter be referred to as the “panel”, the “solar panel” or the “solar collector panel”.

A frame surrounding these panels is generally made from a metal or plastic material, and is attached permanently to them so that they can be maintained, and enabling them to be fitted or installed, particularly on building structures.

These frames must assure a sturdy, water-tight join with the mounting plate itself and may be produced particularly using extruded profile members made from aluminium alloy or polymer, particularly of the PVC type.

Frames of such kind are well known, for example from patent application DE 196 52 658 A1, also DE 197 00 873 A1 and EP 1860705 A1.

In cases where such frames are fabricated using long sections of an aluminium alloy profile member, as described in particular in the first patent application cited above, the profile member generally has a U-shaped cross-section into which the panel is inserted.

The various profile member long sections, cut to size in advance and chamfered at the ends, are then mounted one at a time or simultaneously on the different sides of the panel in just the same way as a frame is created in more the more familiar applications of painting or pictures.

In order to make a sturdy, water-tight assembly, one of two solutions is generally adopted:

Before mounting, attaching self-adhesive tape in the U-shaped section of the profile member or to the edges of the panel borders that will be inserted, the tape being preferably of the adhesive foam type, typically 1.2 to 1.7 mm thick, known to those skilled in the art as “foam tape”, which allows insertion with significant pressure and creates a permanent join,

Applying a product of the type known to those skilled in the art as “silicone mastic” or “silicone sealant” in the U-shaped section of the profile member, which product will fill all gaps between the inside of said section and said panel when it is inserted, and will ensure adhesion and water-tightness by subsequently hardening.

### Definition of the Problem

Unfortunately, the solutions described in the preceding are associated with a number of drawbacks, which in particular have the effect of rendering the automation of frame mounting/assembly operations extremely complicated or even completely impossible.

At all events, the need to insert the various edges of the panel into the U-shaped section in the lengths of the profile member means that it is impossible to carry out the fabrication of the panels and the empty frame separately and join the two subassemblies by automated or robotic means.

In fact, it is only possible to insert each side of the panel one at a time, or at the best two at a time, in the U-shaped sections in the lengths of profile members that have been cut and chamfered beforehand in order to assemble the ends thereof at an angle.

It is generally necessary to provide a method for adjusting the angles or squareness of the frame that is shaped in this way.

But most importantly in the case of the first solution, whether the self-adhesive tape is arranged along the edges all around the panel or inside the U-shaped section of the lengths of the profile members, since the operation of inserting the panel must ensure both adhesion and water-tightness, necessitating very limited play between the inside of the U-shaped section of the profile member lengths and the panel, this operation must be carried out extremely carefully to avoid damaging the self-adhesive tape to the slightest degree, since this would impair the strength of the assembly and increase the risk of loss of watertightness.

Furthermore, besides the concerns regarding the risk of damaging the tape, insertion is also rendered more difficult by the fact that the panel sticks to the insider of the profile member section as soon as the two elements come into contact.

One known solution for making insertion easier by “sliding” the panel inside the U-shaped section of the profile member length consists of coating at least part of the panel beforehand with a soapy solution.

However, this solution is associated with a significant drawback in that it is accompanied by the risk of reducing final adhesion and particularly of introducing liquid and contamination to the production lines involved.

Regarding the second solution, it is scarcely possible to apply the “mastic” or “silicone sealant” except by hand, which is still an intricate job, as is the remove of excess material after the assembly, which proves to be just as difficult and time-consuming.

Finally, a temporary storage area must be provided to enable the “silicone sealant” time to harden, and its performance over time when exposed to ultra-violet radiation is not entirely satisfactory.

### OBJECT OF THE INVENTION

The object of the invention is therefore an extruded profile member for a solar panel frame, characterised in that it comprises a cross-section defined by at least three surfaces (1), (3) and (5) for forming, after being shaped, typically by folding and clamping, an essentially U-shaped cross-section that supports the panel (6) therein, and because of the extrusion operation before they are shaped, the three surfaces forming between them an angle that is sufficient to enable the panel (6) to be positioned on one of said three surfaces (1), (3) or (5), typically (5), without allowing the panel (6) to touch either of the other surfaces, typically (1) and (3), while it is being positioned.

According to a preferred embodiment, real intersection lines (2) and (4) of the three surfaces (1), (3) and (5) are designed, typically by the presence of bending radii, such that they are able to be bent essentially at right angles after the panel has been positioned on one of the three surfaces, typically (5), so that the other two surfaces may be forced against the panel by clamping.

According to another embodiment, angles are formed inside the profile member between surfaces (1) and (3) and surfaces (3) and (5) along real intersection lines (2) and (4) thereof, such that the panel may be moved into a final position on the one fixed surface (5) of the three surfaces of the profile member in a translation movement essentially perpendicular to said surface (5) without allowing panel (6) to touch the other two surfaces (1) and (3) during this positioning movement, the other two surfaces being intended for bending and clamping against panel (6) during shaping.

More preferably still, the thicknesses of the profile member along real intersection lines (2) and (4) of said three surfaces (1), (3) and (5) inside the profile member are reduced by the presence of a radius centred on said lines.

According to an advantageous embodiment, at least one of the surfaces (1), (3) and (5) is coated with self-adhesive tape or “adhesive foam”, known to those skilled in the art and typically having a thickness from 1.2 to 1.7 mm for attaching the panel to the frame profile member while it is being positioned.

According to another embodiment, none of the surfaces (1), (3) and (5) is coated with a self-adhesive tape or “adhesive foam” as described above, the adhesive is deposited on the panel itself before it is moved into position.

According to one of the implementation modes of the invention, said profile members on the various sides of the frame are positioned and folded over the panel independently of each other or in pairs.

According to a yet more advantageous embodiment, the frame, which is typically rectangular, is fabricated from profile member lengths entirely separately that have been assembled before the shaping operation, typically in the shape of a rectangle formed by four lengths, the panel being positioned subsequently on the fixed surface (5) of the profile member lengths of the frame and the other surfaces (1) and (3) of the profile members are folded over said panel.

According to a further preferred embodiment, the four profile member lengths are produced as a single piece, that is to say the four lengths that make up the assembly are not detached, the angles of the rectangle being made by flaring and bending the profile member lengths, and the frame being mounted as a closed assembly with the aid of an angle joining element (7) typically made from cut-off piece of the extruded profile element, such as is known to one skilled in the art.

Finally, the profile members are advantageously made from aluminium alloy, typically from the EN AW-6000 or EN AW-2000 or EN AW-7000 series in accordance with European standard DIN EN 573-3.

At all events, the invention will be better understood upon reading the following description and with reference to the accompanying diagrammatic figures, which illustrate various modes of implementation of the invention for exemplary purposes only and without limitation thereto.

### DESCRIPTION OF THE DRAWING

FIG. 1 shows a cross-section of the profile member according to the invention intended to accommodate panel (6), a part of which is also shown during positioning in a movement in the direction of the arrow towards surface (5), with surfaces (1), (3) and (5) as well as their intersection lines (2) and (4). The angles between surfaces (1) and (3) and between (3) and (5) along lines (2) and (4) are 125° in the figure.

FIG. 2 shows a profile member according to the invention equipped with a section such as in the preceding figure, and the first approach sequence for positioning panel (6), against surface (5) in the figure.

FIG. 3 shows the next two sequences and the final result: in 3/1 of forming the section of the profile member by bending to bring surface (3) into contact with the second edge of the panel, and in 3/2 bending and final clamping to fold the U-shaped profile member against the panel, fixing the panel in the section, which will now be permanently in a U-shape, as in 3/3.

FIG. 4 shows the assembly of a rectangular frame produced from four profile member lengths in a single part, the angles of the rectangle being created by flaring and bending said profile member lengths. At this stage, the sections of said profile member lengths may still be open, so that the panel may still be positioned afterwards on surface (5) of the frame profile lengths, and the other surfaces of the profile members may be folded over on said panel.

FIG. 5 shows a view of the frame of the preceding figure, in a zone described by the circle in FIG. 4, where the frame is closed with the aid of an angle joining element (7) such as is known by one skilled in the art, and in this case fabricated from a cut-off part of extruded profile member, furnished with claws, inserted in a groove inside the two profile member lengths to be assembled, in this case at an angle of 90°.

FIG. 6 shows the profile member used for bending tests, dimensions being given in mm, all radii not shown are 0.5 mm.

FIG. 7 shows an enlarged view of the U-shaped section of the same profile member, open before the panel is positioned, on the horizontal part 5 of the section, then bending of walls 3 and 1 in sequence. Here too, dimensions are given in mm. The value of a is 127°, 1 is equal to 11 mm, b is equal to 6 mm, x is equal to 0.58 mm and h is 3.6 mm.

### DETAILED DESCRIPTION OF THE INVENTION

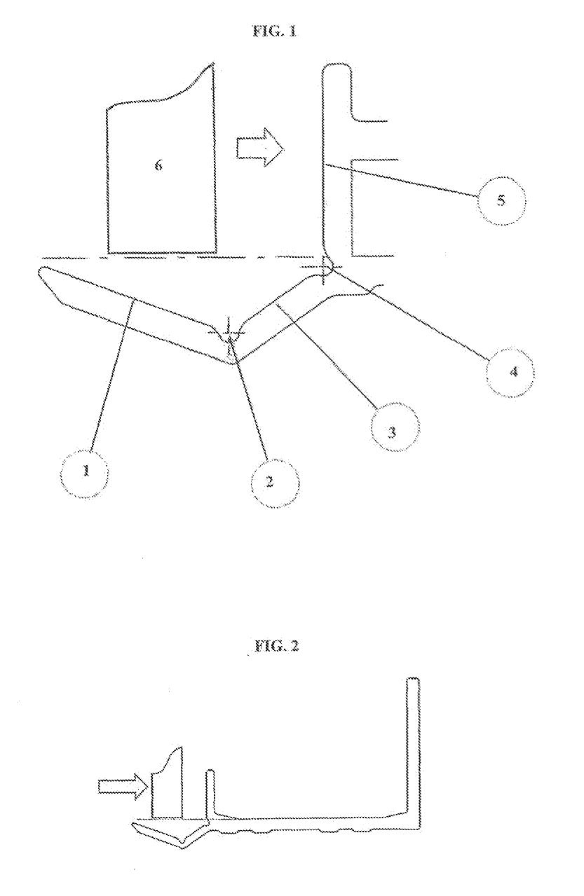

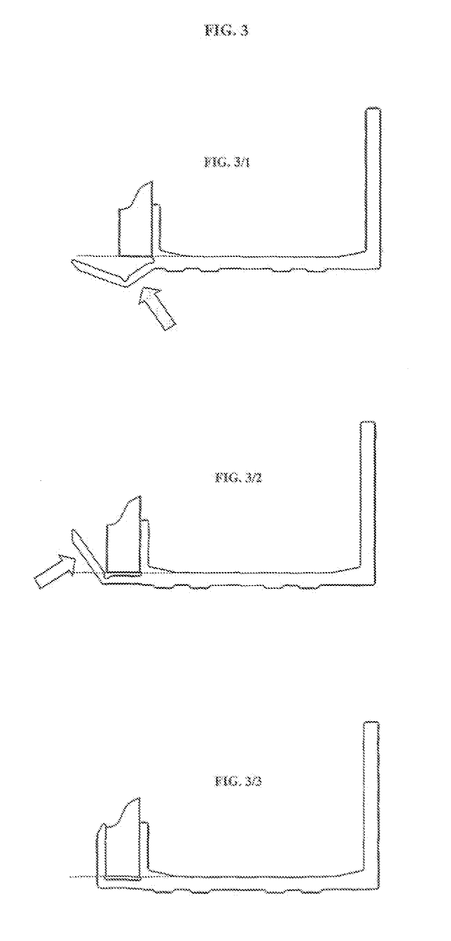

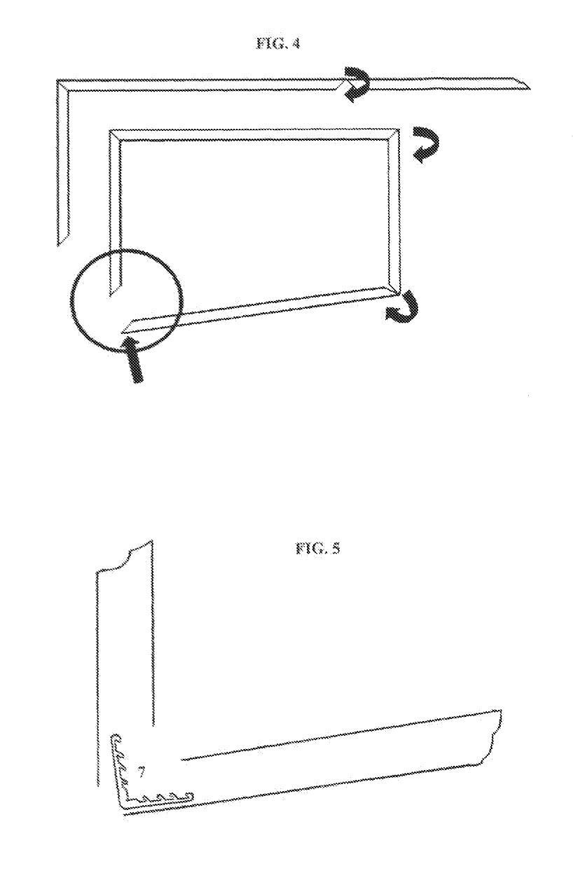

The invention is founded on the applicant's realisation that in order to produce a solar panel frame that in its final configuration forms a U-shaped section surrounding and covering the panel while being permanently attached to the sills around the entire periphery of the panel assembly it is possible to use a profile member having an initial cross-section obtained by extrusion that is more open than a U-shaped cross-section which, after the panel has been positioned and attached to one of the surfaces of said section, typically surface (5) as shown in FIG. 1, is closed, typically with the aid of a press, to bring surfaces (3) and (1) against the other edges of panel (6), thereby recreating the U-shaped cross-section of the frame that encloses the panel.

More precisely, immediately after the extrusion operation has been performed and before the shaping operation the three surfaces of the essentially U-shaped cross-section of the profile member between them form an angle sufficient to allow the panel to be positioned, typically on surface (5), without allowing panel (6) to touch the other surfaces, typically (1) and (3), during the course of positioning, which surfaces are subsequently folded around it.

As for the implementation according to the known prior art, a relatively thick (typically from 1.2 to 1.7 mm) self-adhesive tape, soft enough to conform to the variations in the surface condition or dimensional tolerances, known to those skilled in the art as “foam adhesive” or “foam band”, is placed before assembly, typically on two sides, (5) and (1) as shown in FIG. 1, of the inner cross-section of the profile member, or on the corresponding facing surfaces of the panel, and very frequently on at least part of the surface (3) or the corresponding facing surface of the panel.

Once the section has been folded over the panel, this tape ensures both that the frame is bonded to the panel and that the joint between the frame and panel is watertight, which is extremely important when the assembly is set up outdoors, particularly on building structures. The problems associated with the difficulty of inserting the panel in the U-shaped cross section of the profile member due to the presence of the self-adhesive tape as described in the preceding are thus solved because the panel may be brought into contact with one of the surfaces, usually but not always surface (5), without touching the other surfaces while it is being placed in this way.

It is also evident that since this method simplifies the placing and positioning of the profile members on the panel, it is also possible and relatively easy for the process to be automated or performed by robots, and since such automation is associated with extreme precision, the need to adjust the angles or alignment of the frame shaped in this way may be reduced significantly or even eliminated entirely, representing a considerable economy.

In order to simplify the bending of the profile members with a press, one the panel is in place radii may be provided, obtained directly while the profile member is was extruded, typically inside the cross-section of the profile member, along the fold lines, that is to say the real intersection lines (2) and (4) of surfaces (1), (3) and (5) according to FIG. 1.

The applicant found that, surprisingly, this mode of operation had the advantage that not a single adverse incident occurred regarding the coating or any possible surface treatment, which is typically created by anodising in the case of aluminium alloy profile members, and particularly such as is known as “Eloxal” to those skilled in the art.

But the invention is even more advantageous is, as shown in FIG. 1, the angles between surfaces (1) and (3) and between (3) and (5), which are typically 125° in the case of FIG. 1, are large enough to allow the panel to be positioned with a translation movement along an axis essentially perpendicular to surface (5), so that the panel may be positioned and affixed there, typically by adhesion, without touching the other surfaces of the profile member section concerned.

It is then possible to fabricate the frame by assembling sections of lengths, possibly cut so size beforehand, of the profile members whose cross-section is still open, that is to say before they are shaped, typically into a rectangle formed by four lengths, in a separate step that lends itself readily to automation or processing by robots. The panel, which is manufactured elsewhere, may then be positioned and fixed in place very easily, typically by adhesion with a self-adhesive tape of the type described previously, on the surface (typically (5) as shown in FIG. 1) of the frame profile member lengths prefabricated in this way, and the other open surfaces of the profile members folded over on the panel, to insert it in a section of the profile members that has thus been bent into a U-shape.

In a more preferred implementation, the frame, which is typically rectangular, is assembled from lengths (typically four) of profile members that have not been cut into separate segments beforehand, as in the preceding case, but from a single profile member according to the invention that is in a single piece.

In this case, as indicated in FIG. 4, the angles of the rectangle are created by flaring into a V-shape of 90° and bending the profile member lengths.

In order to facilitate bending, as for the bending of profile member sections described previously, radii may be created, typically by machining, at the same time or in the same step as the flaring operation described in the preceding, inside the profile member along the bending axis or the real intersection line of surfaces (1) and (3) and of (3) and (5).

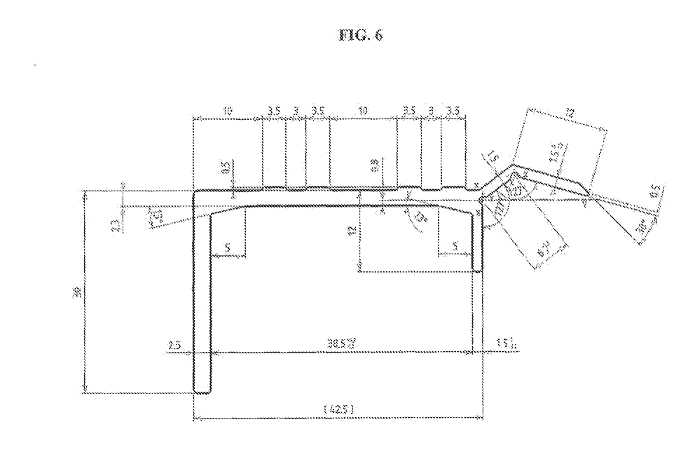

According to this last implementation type, for assembling the last two profile member lengths and completing the assembly of the frame before the panel is fitted, an angle joining element (7) such as is shown in FIG. 5 and known to those skilled in the art may be used.

This is typically an offcut from the extruded profile member, furnished with claws that prevent it from being removed after insertion in a groove typically provided inside the two profile member lengths that are to be joined, in this case at an angle of 90°.

However, this final assembly may be performed, without limitation thereto, by riveting, clinching or spot welding.

Finally, the material used for extruded profile members is typically an aluminium alloy, particularly of series EN AW-6000, EN AW-2000 or EN AW-7000, according to the European standard DIN EN 573-3, but it may also be a polymer particularly of the PVC type.

### EXEMPLARY EMBODIMENT

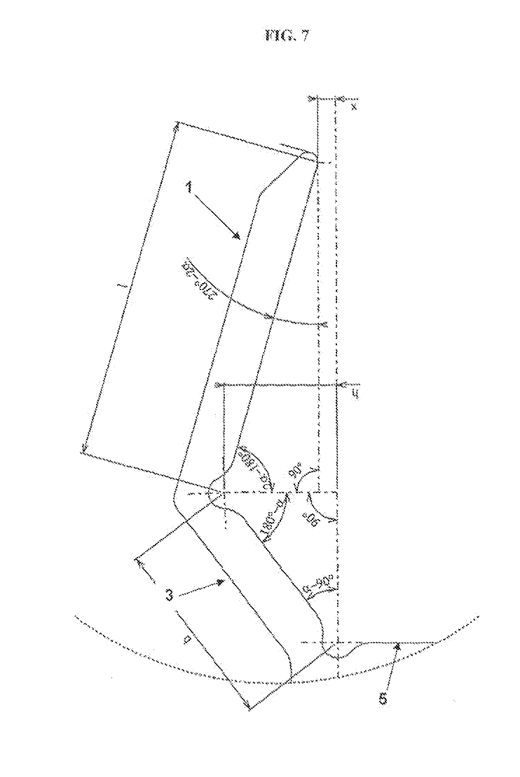

A profile member as shown in FIG. 6 (dimensions in mm) was produced by extrusion on a 22 MN press, in an alloy of type EN AW-6060 in metallurgical state T5 (quenched on press).

An enlarged view of the open U-shaped cross-section is shown in FIG. 7 (dimensions also given in mm).

For these tests, we used a solar panel comprising a film known to those skilled in the art as PVF (polyvinyl fluoride) and manufactured by “DUPONT”, and known more exactly by its commercial name “Tedlar”, solar cells and a layer of glass, the entire assembly having thickness of 4 mm.

The entire periphery of the panel is covered on both sides with a self-adhesive tape having a thickness of 1 mm, the tape being made from polyethylene foam and coated on both sides with acrylic adhesive (known to those skilled in the art by the name “PE Acryl”) with a width of 22 mm manufactured by “TESA” under reference “Tesa 4957”.

The profile member was inserted in a steel frame having an internal volume indicated on length section 38.5 in FIG. 6.

The panel was then positioned on the face of the profile member, horizontal in FIG. 7.

Initially, wall 3 was bent to about 37° as shown in FIG. 7 to force the inner surface against the self-adhesive tape on the panel.

The same procedure was carried out on wall 1, to force the inner surface against the self-adhesive tape on the panel and thus fold the U-shaped section around it.

1. An extruded profile member for a solar collector panel, wherein said member comprises a cross-section defined by at least three surfaces for forming, after being shaped, optionally by folding and clamping, an essentially U-shaped cross-section that supports a panel therein, said three surfaces forming among them due to an extrusion operation, an angle that is sufficient before said shaping to enable said panel to be positioned on one of said three surfaces without allowing said panel to touch either of the other said surfaces while being positioned.

2. The profile member as claimed in claim 1, wherein real intersection lines of said three surfaces are designed, optionally by the presence of bending radii, such that said bending radii are able to be bent essentially at right angles after said panel has been positioned on one of said three surfaces, so that said other two surfaces may be forced against said panel by clamping.

3. The profile member as claimed in claim 1, wherein angles are formed inside said profile member between at least two of said surfaces along said real intersection lines thereof, such that said panel may be moved into a final position on one of said surfaces comprising a fixed surface of said profile member in a translation movement essentially perpendicular to said fixed surface without allowing said panel to touch said other two surfaces during positioning movement, said other two surfaces being intended for bending and clamping against said panel during shaping.

4. The profile member as claimed in claim 1, wherein the thicknesses of said profile member along said real intersection lines of said three surfaces inside said profile member are reduced by the presence of a radius centred on said real intersection lines.

5. The profile member as claimed in claim 1, wherein at least one of said three surfaces is coated with self-adhesive tape or adhesive foam, optionally having a thickness from 1.2 mm to 1.7 mm for fixing said panel in place while being positioned.

6. The profile member as claimed in claim 1, wherein none of said surfaces are coated with a self-adhesive tape or adhesive foam, and wherein adhesive is deposited on said panel before said panel is moved into position.

7. A frame for a solar collector panel produced from at least one profile member as claimed in claim 1, wherein said profile member on various sides of said frame is positioned and folded over said panel independently of other profile members or in pairs.

8. A frame for a solar collector panel, optionally rectangular, fabricated from at least one profile member as claimed in claim 1, wherein said profile member has been assembled before the shaping operation, optionally in the shape of a rectangle formed by four lengths of said profile member, said panel being positioned subsequently on a fixed surface of said profile member lengths of the frame and said other surfaces of the profile member are folded over said panel.

9. The frame as claimed in claim 8, wherein four profile members are produced as a single piece, the angles of the rectangle being made by flaring and bending said profile member lengths, and said frame being mounted as a closed assembly with the aid of an angle joining element optionally made from a cut-off piece of an extruded profile element.

10. The frame as claimed in claim 7, wherein said profile member comprises an aluminium alloy, said alloy optionally comprising EN AW6000 or EN AW2000 or EN AW7000 series in accordance with European standard DIN EN 573-3.
